(19) United States
(12) Patent Application Publication
(10) Pub. No.: US 2016/0091788 A1
(43) Pub. Date: Mar. 31, 2016

(54) IMPRINT MOLD AND METHOD FOR DESIGNING DUMMY PATTERN

(71) Applicant: DAI NIPPON PRINTING CO., LTD., Tokyo (JP)

(72) Inventors: Yuki ARITSUKA, Tokyo (JP); Naoko NAKATA, Tokyo (JP)

(73) Assignee: DAI NIPPON PRINTING CO., LTD., Tokyo (JP)

(21) Appl. No.: 14/785,700

(22) PCT Filed: Apr. 16, 2014
(86) PCT No.: PCT/JP2014/060801

§ 371 Date: Oct. 20, 2015

(30) Foreign Application Priority Data
Apr. 22, 2013 (JP) 2013-089355

(51) Int. Cl. G03F 7/00; B29C 59/02

(52) U.S. Cl. CPC G03F 7/0002; B29C 59/022; B29C 59/026

(57) ABSTRACT

An imprint mold that has, in a pattern region on a principal surface of a base material, a main pattern with an uneven structure and a dummy pattern with an uneven structure for assisting transfer of the main pattern, wherein at least one end portion of a concave structure or a convex structure of the dummy pattern reaches an outermost periphery of the pattern region, and a closed region that is surrounded with one or more concave structures or convex structures of the dummy pattern does not exist in the pattern region when the imprint mold is planarly viewed.

### TECHNICAL FIELD

The present invention relates to an imprint mold and a method for designing a dummy pattern for the imprint mold.

### BACKGROUND ART

Nanoimprint technology, also known as the microfabrication technology, is a pattern forming technique that uses a mold member (imprint mold) configured by forming a fine uneven pattern on a surface of a base material and transfers the fine uneven pattern to a subject to be processed to obtain a fine uneven pattern in the same size (see PATENT DOCUMENT 1). Especially in view of further miniaturization of the wiring pattern and the like of a semiconductor device, the nanoimprint technology for a semiconductor device producing process and the like has been gaining more and more attention.

In this nanoimprint technology, generally an imprint resin used as a subject to be processed is dropped discretely on a substrate, and the imprint resin droplets and an imprint mold are brought into contact with each other to wet and spread the imprint resin over the entire region on the imprint mold where a fine uneven pattern is formed (pattern region). In this state, the imprint resin is hardened and the fine uneven pattern of the imprint mold is transferred, thereby forming a fine uneven pattern structure.

In order to form a fine uneven pattern structure with a high degree of accuracy using the nanoimprint technology, the imprint resin needs to sufficiently fill the fine uneven pattern (concave portions) to be transferred, when the imprint resin is wet and spread. This is because when there exists a part in the fine uneven pattern (concave portions) that is not sufficiently filled with the imprint resin, pattern defects might be caused.

A method for hardening the imprint resin after bringing the imprint mold into contact with the imprint resin and then securing enough time to fill the pattern with the imprint resin has been considered as a way to not cause such pattern defects. Unfortunately, lengthening of the time it takes to fill the pattern with the imprint resin could lead to a decrease in throughput.

For the purpose of reducing the time it takes to fill the pattern with the imprint resin, there has been proposed an imprint mold that has a fine pattern to be transferred and a concave dummy pattern larger than the fine pattern, wherein a plurality of convex portions are provided in the concave dummy pattern (see PATENT DOCUMENT 2).

### PRIOR ART LIST

### Patent Document

[PATENT DOCUMENT 1] U.S. Pat. No. 5,772,905
[PATENT DOCUMENT 2] Japanese Patent Application Publication No. 2011-249817

### SUMMARY OF INVENTION

### Problems to be Resolved by the Invention

In the imprint mold disclosed in PATENT DOCUMENT 2, the dummy pattern is transferred to a substrate to be processed (imprint resin applied to a substrate to be processed) and provided for the purpose of reducing fluctuations of the in-plane pattern density in the substrate to be processed. PATENT DOCUMENT 2 also describes that the volume of the concave dummy pattern is reduced due to the presence of the plurality of convex portions in the concave dummy pattern, and that consequently the amount of imprint resin to fill the dummy pattern can be reduced, accomplishing a reduction in time it takes to fill the dummy pattern with the imprint resin.

However, in order to reduce the time it takes to fill the pattern with the imprint resin and prevent non-filling of the fine uneven pattern of the imprint mold, the pattern needs to be designed in consideration of how the imprint resin flows when wetting and spreading the imprint resin. Especially in an imprint mold that is used for the purpose of forming an uneven pattern having fine dimensions (e.g., a half-pitch of approximately 50 nm or less), the imprint resin is wet and spread to fill the pattern by taking advantage of the function of the capillary force of the concave portion of the fine uneven pattern of the imprint mold. In order to do so, the pattern needs to be designed particularly in consideration of how the imprint resin flows in the concave portion of the dummy pattern.

In view of this aspect, the continuous concave portion between the plurality of convex portions (pillar-shaped convex portions) inside the concave dummy pattern of the imprint mold disclosed in PATENT DOCUMENT 2 can be taken as the flow path for wetting and spreading the imprint resin. Therefore, in terms of the fact that the flow path through which the imprint resin flows exists, the imprint mold disclosed in PATENT DOCUMENT 2 employs a favorable pattern arrangement.

However, in a mold that is produced through imprint lithography by using the imprint mold of PATENT DOCUMENT 2 as a master mold (a replica mold), a plurality of concave portions (hole-shaped concave portions) are formed to correspond to the plurality of convex portions. In other words, the uneven structure of the master mold is reversed in the replica mold.

In the nanoimprint technology, generally an imprint process is performed using an expensive master mold produced through an electron beam (EB) lithography, to produce a number of replica molds that each have a fine uneven pattern obtained by reversing the fine uneven pattern of the master mold. The imprint process is performed using these replica molds.

Therefore, the dummy pattern of the master mold needs to be designed to not block the flow of the imprint resin, not only in the imprint process that uses the master mold but also in the imprint process that uses the replica molds that each have a fine uneven pattern obtained by reversing the fine uneven pattern of the master mold.

From this perspective, the replica molds that are obtained from the imprint mold disclosed in PATENT DOCUMENT 2 bring about a problem that the flow of the imprint resin is blocked because the plurality of concave portions are independent (isolated) and therefore do not produce a continuous flow path for the imprint resin. Consequently, the invention disclosed in PATENT DOCUMENT 2 is far from being able to prevent sufficiently the occurrence of defects caused by not filling the pattern with the imprint resin.

In view of the foregoing problems, an object of the present invention is to provide: an imprint mold comprising a dummy pattern that does not block the flow of an imprint resin for both a master mold and a replica mold, with the replica mold having a fine uneven pattern obtained by reversing the fine uneven pattern of the master mold; and a method for designing the dummy pattern for the imprint mold.

### Means of Solving the Problems

In order to solve the foregoing problems, the present invention provides an imprint mold that is configured by forming, in a pattern region on a principal surface of a base material, a main pattern with an uneven structure and a dummy pattern with an uneven structure for assisting transfer of the main pattern, wherein at least one end portion of a concave structure of the dummy pattern reaches an outermost periphery of the pattern region, and a closed region that is surrounded with one or more concave structures of the dummy pattern does not exist in the pattern region when the imprint mold is planarly viewed (invention 1).

In the foregoing invention (invention 1), it is preferred that both end portions of the concave structure of the dummy pattern reach the outermost periphery of the pattern region (invention 2). In this invention (invention 2), it is preferred that the pattern region be a substantially square region and that the both end portions of the concave structure of the dummy pattern respectively reach different sides configuring the substantially square pattern region (invention 3).

In the foregoing inventions (inventions 1 to 3), it is preferred that the imprint mold comprises a base portion and a projected structure portion protruding from a surface of the base portion, and that the outermost periphery of the pattern region be located on the inside of an outermost periphery of the projected structure portion (invention 4). In this invention (invention 4), it is preferred that at least one end portion of the concave structure of the dummy pattern be located on a side of the outermost periphery of the pattern region between the outermost periphery of the projected structure portion and the outermost periphery of the pattern region (invention 5).

In the foregoing inventions (inventions 1 to 5), it is preferred that the pattern region be a region in which a plurality of pattern small regions are arranged in array, that the main pattern and the dummy pattern be formed in each of the plurality of pattern small regions, that, from among the plurality of pattern small regions, at least one end portion of a concave structure of a dummy pattern formed in the pattern small region that is located at the outermost periphery of the pattern region reach the outermost periphery of the pattern region, and that a concave structure of the dummy pattern formed in one of the pattern small regions be connected to a concave structure of the dummy pattern formed in another pattern small region adjacent to the pattern small region (invention 6).

The present invention also provides a method for designing a dummy pattern for an imprint mold that is formed with, in a pattern region on a principal surface of a base material, a main pattern with an uneven structure and the dummy pattern with an uneven structure for assisting transfer of the main pattern, the method comprising: a dummy pattern region setting step of setting a dummy pattern region for forming the dummy pattern in the pattern region of the imprint mold; and a dummy pattern arrangement step of arranging the dummy pattern in the dummy pattern region, wherein, in the dummy pattern arrangement step, the dummy pattern is arranged in the dummy pattern region in such a manner that at least one end portion of a concave structure of the dummy pattern reaches an outermost periphery of the pattern region and that a region surrounded with one or more of the dummy patterns is not formed within the dummy pattern region (invention 7).

In the foregoing invention (invention 7), it is preferred that, in the dummy pattern arrangement step, the dummy pattern is arranged in the dummy pattern region in such a manner that both end portions of the concave structure of the dummy pattern reach the outermost periphery of the pattern region (invention 8).

In the foregoing invention (invention 8), the dummy pattern region may be divided into a plurality of unit regions, and the dummy pattern arrangement step may arrange, in the dummy pattern region, a region configured by connecting any two unit regions to each other with other unit regions therebetween, as the concave structure or convex structure of the dummy pattern, these two random unit regions being located respectively at the outermost periphery of the pattern region and an outermost periphery of the dummy pattern region (invention 9). Furthermore, the dummy pattern arrangement step may draw a plurality of lines to connect any two points located respectively at the outermost periphery of the pattern region and the outermost periphery of the dummy pattern region, and arrange two adjacent lines out of the plurality of lines in the dummy pattern region as the concave structure or convex structure of the dummy pattern (invention 10).

In the foregoing inventions (inventions 7 to 10), it is preferred that the imprint mold comprises a base portion and a projected structure portion protruding from a surface of the base portion, and that the outermost periphery of the pattern region be located on the inside of an outermost periphery of the projected structure portion (invention 11).

In the foregoing invention (invention 11), it is preferred that, in the dummy pattern arrangement step, the dummy pattern is arranged in the dummy pattern region in such a manner that at least one end portion of the concave structure of the dummy pattern is located on a side of the outermost periphery of the pattern region between the outermost periphery of the projected structure portion and the outermost periphery of the pattern region (invention 12).

In the foregoing inventions (inventions 7 to 12), it is preferred that the pattern region be a region in which a plurality of pattern small regions are arranged in array, that the dummy pattern region setting step set a dummy pattern region for forming the dummy pattern in each of the pattern small regions, and that the dummy pattern arrangement step arrange the dummy pattern in such a manner that, from among the plurality of pattern small regions, at least one end portion of the concave structure of the dummy pattern within the dummy pattern region of a pattern small region located at the outermost periphery of the pattern region reaches the outermost periphery of the pattern region and that the concave structure of the dummy pattern within the dummy pattern region of one of the pattern small regions is connected to the concave structure of the dummy pattern within the dummy pattern region of another pattern small region adjacent to the pattern small region (invention 13).

The present invention further provides a pattern formation method that places, face to face, a substrate to be processed, one surface of which is fed with a material to be transferred, and the imprint mold of any of the inventions (inventions 1 to 6), brings the principal surface of the imprint mold into contact with the material to be transferred, expands the material to be transferred between the principal surface of the imprint mold and the one surface of the substrate to be processed, hardens the material to be transferred, and then separates the hardened material to be transferred from the imprint mold (invention 14).

A replica mold can be produced by placing a substrate to be processed, one surface of which is fed with a material to be transferred, and the imprint mold of any of the inventions (inventions 1 to 6) face to face, bringing the principal surface of the imprint mold into contact with the material to be transferred, expanding the material to be transferred between the principal surface of the imprint mold and the surface of the substrate to be processed, hardening the material to be transferred, and then separating the hardened material to be transferred from the imprint mold. Pattern formation is also possible by placing a substrate to be processed, one surface of which is fed with a material to be transferred, and the replica mold face to face, bringing a principal surface of the replica mold into contact with the material to be transferred, expanding the material to be transferred between the principal surface of the replica mold and the surface of the substrate to be processed, hardening the material to be transferred, and then separating the hardened material to be transferred from the replica mold.

### Advantageous Effects of Invention

The present invention can provide: an imprint mold comprising a dummy pattern that does not block the flow of an imprint resin for both a master mold and a replica mold, with the replica mold having a fine uneven pattern obtained by reversing the fine uneven pattern of the master mold; and a method for designing the dummy pattern for the imprint mold.

### BRIEF DESCRIPTION OF DRAWINGS

FIG. 1 shows a plan view (FIG. 1(a)) and a cross-sectional diagram (FIG. 1(b)), showing a schematic configuration of an imprint mold according to an embodiment of the present invention.

FIG. 2 is a plan view, schematically showing a pattern region of the imprint mold according to the embodiment of the present invention.

FIG. 3 is a plan view, schematically showing an example of a dummy pattern of the imprint mold according to the embodiment of the present invention.

FIG. 4 is a perspective view, schematically showing the configurations of a concave portion (FIG. 4(a)) and a convex portion (FIG. 4(b)) of the imprint mold according to the embodiment of the present invention.

FIG. 5 is a plan view (1), schematically showing the configuration of the dummy pattern of the imprint mold according to the embodiment of the present invention.

FIG. 6 is a plan view (2), schematically showing the configuration of the dummy pattern of the imprint mold according to the embodiment of the present invention.

FIG. 7 is a flowchart showing the steps of a dummy pattern designing method according to the embodiment of the present invention.

FIG. 8 is a plan view, showing examples of a pattern region, a main pattern region, and a dummy pattern region, which are set by the dummy pattern designing method according to the embodiment of the present invention.

FIG. 9 is a plan view showing an example of a step of the dummy pattern designing method according to the embodiment of the present invention, in which the dummy pattern region is divided into a plurality of unit regions.

FIG. 10 is a plan view, showing an example of designating two of the plurality of unit regions obtained by dividing the dummy pattern region shown in FIG. 9.

FIG. 11 is a plan view, showing an example of designating the plurality of unit regions obtained by dividing the dummy pattern region shown in FIG. 9, to form a designated region.

FIG. 12 is a plan view showing an example of a method for forming the designated region shown in FIG. 11.

FIG. 13 is a plan view showing an example of how a non-designated region surrounded by two designated regions is formed.

FIG. 14 is a plan view, schematically showing the configuration of a pattern region of an imprint mold according to another embodiment of the present invention.

FIG. 15 is a plan view, schematically showing the configuration of a concave portion of a dummy pattern of the imprint mold shown in FIG. 14.

### DESCRIPTION OF EMBODIMENTS

Embodiments of the present invention are described hereinafter with reference to the drawings.

### [Imprint Mold]

The following example is described as an imprint mold according to the present embodiment: an imprint mold in which a pattern formation surface thereof has two types of fine uneven patterns formed thereon, a fine uneven pattern to be transferred to a substrate to be processed through an imprint process using the imprint mold (referred to as “main pattern,” hereinafter) and a fine uneven pattern to be transferred to the substrate to be processed along with the main pattern (referred to as “dummy pattern,” hereinafter). The dummy pattern is provided for the purpose of improving the accuracy of the imprint process by improving, for example, the detachability of the imprint mold in the imprint process and the fillability of imprint resin in the concave portions of the fine uneven patterns (the main pattern and the dummy pattern) of the imprint mold.

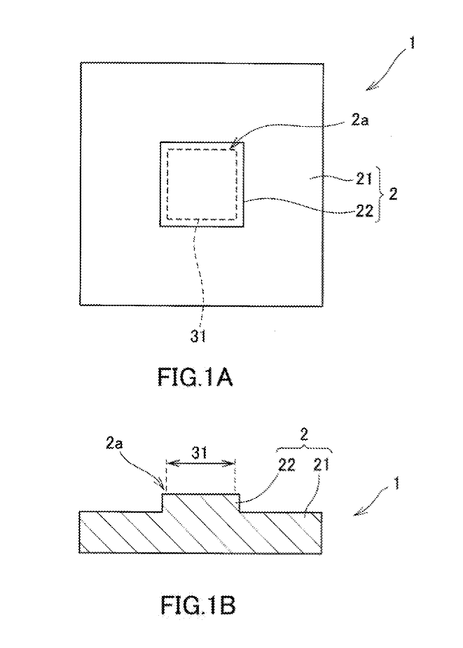

As shown in FIGS. 1(a) and 1(b), an imprint mold 1 according to the present embodiment has a base material 2, and the main pattern and the dummy pattern (both not shown) that are formed in a pattern region 31 of a principal surface (the side on the base material 2 on which the patterns are formed) 2a of the base material 2.

For the base material 2 of the imprint mold 1, the present embodiment illustrates an example that has a base portion 21 and a projected structure (mesa structure) 22 projecting from one surface of the base portion 21 (see FIG. 1); however, the base material 2 is not limited to this aspect and may be in the form of a flat plate without the mesa structure.

The base material 2 can be selected according to the use of the imprint mold 1 (for optical imprinting, thermal imprinting, etc.), and examples of the base material 2 include a substrate that is generally used for producing an imprint mold (e.g., transparent substrates such as glass substrates, including quartz glass, soda-lime glass, fluorite, a calcium fluoride substrate, a magnesium fluoride substrate, and acrylic glass, resin substrates, including a polycarbonate substrate, a polypropylene substrate, and a polyethylene substrate, and laminated substrates each obtained by laminating two or more substrates selected randomly from the foregoing substrates; metal substrates such as a nickel substrate, a titanium substrate, and an aluminum substrate; semiconductor substrates such as a silicon substrate and a gallium nitride substrate).

The thickness of the base material 2 can be set properly between, for example, 300 μm and 10 mm in consideration of the strength, handling properties and the like of the substrate. The term “transparent” described in the present embodiment means that the transmittance of a light beam with a wavelength of 300 to 450 nm is 85% or higher, preferably 90% or higher, and more preferably 95% or higher.

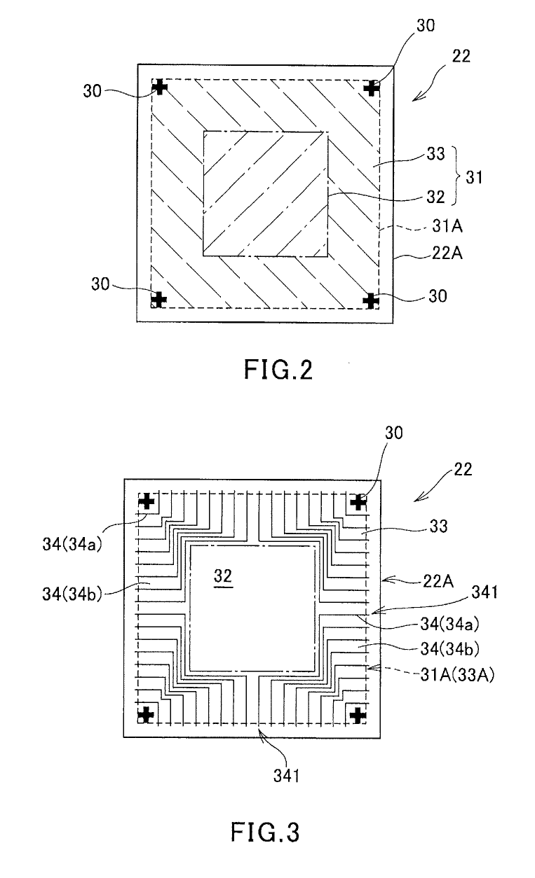

As shown in FIG. 2, the main pattern is a fine uneven pattern with an uneven structure (with concave portions and convex portions), which is formed in a main pattern region 32 included in the pattern region 31 on the principal surface 2a of the base material 2. The illustration of the main pattern is omitted in FIG. 2.

In the present embodiment, the pattern region 31 is a region on the mesa structure 22 of the imprint mold 1, wherein an outermost periphery 31A of the pattern region 31 is located on the inside of an outermost periphery 22A of the mesa structure 22 as viewed planarly. Specifically, the pattern region 31 is a substantially square region in which each of the apexes has an alignment mark 30 that is formed at least in the vicinity of each of the four corners of the mesa structure 22. This pattern region 31 is a region where the imprint resin needs to be wet and spread by the imprint process using the imprint mold 1 according to the present embodiment. Furthermore, in the present embodiment, an example of a substantially square region located substantially at the center of the pattern region 31 in the base material 2 is described as the main pattern region 32; however, the main pattern region 32 is not limited to this aspect.

In the present embodiment, the shape of the main pattern can be set according to the shape of a fine uneven pattern that is required in a product and the like produced through the imprint process using the imprint mold 1, and examples of the shape of the main pattern include a line-and-space shape, a hole shape, a pillar shape, and a lattice shape. The size of the main pattern can be set, as appropriate, according to the size of a fine uneven pattern of a product and the like produced through the imprint process using the imprint mold 1 according to the present embodiment.

The dummy pattern is a fine uneven pattern with an uneven structure (with concave portions and convex portions), which is formed inside a dummy pattern region 33 on the principal surface (the pattern formation surface) 2a of the base material 2. In the present embodiment, an example of a region located inside the pattern region 31 of the base material 2 and surrounding the main pattern region 32 is described as the dummy pattern region 33; however, the dummy pattern region 33 is not limited to this aspect. The illustration of the dummy pattern is omitted in FIG. 2.

As shown in FIG. 3, examples of the types of dummy patterns 34 include a fine uneven pattern having substantially an L-shaped concave portion 34a or convex portion 34b, a fine uneven pattern in which the concave portion 34a or convex portion 34b is in the shape of substantially a polygonal line, and a fine uneven pattern in a line-and-space shape.

At least one end portion 341 of the concave portion 34a (or convex portion 34b) of each dummy pattern 34 reaches an outermost periphery 33A of the dummy pattern region 33. In a case where the outermost periphery 31A of the pattern region 31 matches the outermost periphery 33A of the dummy pattern region 33 as in the present embodiment, at least one end portion 341 of the concave portion 34a (or convex portion 34b) of each dummy pattern 34 reaches the outermost periphery 31A of the pattern region 31.

As shown in FIG. 3, it is preferred that the both end portions 341, 341 of the concave portion 34a (or convex portion 34b) of each dummy pattern 34 reach the outermost periphery 31A of the pattern region 31 (the outermost periphery 33A of the dummy pattern region 33). It is more preferred that, when the pattern region 31 is in the shape of substantially a square, the both end portions 341, 341 of the concave portion 34a (or convex portion 34b) of each dummy pattern 34 reach different sides (adjacent sides or opposing sides) out of the sides configuring the outermost periphery 31A of the substantially square pattern region 31.

In the imprint process using the imprint mold 1 according to the present embodiment, a flow path for the imprint resin is constructed of the concave portions 34a of the dummy patterns 34. As in the present embodiment, at least one end portion 341 of the concave portion 34a of each dummy pattern 34 reaches the outermost periphery 31A of the pattern region 31, so at least one end portion 341 of each of the flow paths (flow paths for the imprint resin) constructed of the concave portions 34a of the dummy patterns 34 is positioned at the outermost periphery 31A of the pattern region 31. Because the concave portions 34a of the dummy patterns 34 are not present in the form of regions closed by the convex portions 34b (closed regions) in the pattern region 31 (the dummy pattern region 33), wetting and spreading (flow) of the imprint resin are not inhibited. Consequently, the concave portions 34a of the dummy patterns 34 of the imprint mold 1 can sufficiently be filled with the imprint resin, preventing the occurrence of the defects caused by non-filling of the imprint resin.

Because the both end portions 341, 341 of the concave portion 34a of each dummy pattern 34 reach the outermost periphery 31A of the pattern region 31 (the outermost periphery 33A of the dummy pattern region 33), the flow of the imprint resin in either direction of the end portion 341, 341 of each concave portion 34a is not blocked when the imprint resin flows along the flow path constructed of the concave portion 34a of each dummy pattern 34. Consequently, the occurrence of the defects caused by non-filling of the imprint resin can be prevented effectively.

Producing an imprint mold (replica mold) through imprint lithography by using the imprint mold 1 of the present embodiment as a master mold is now considered. In this case, a concave portion of each dummy pattern on the replica mold (a part that is formed to correspond to the convex portion 34b of each dummy pattern 34 on the master mold) is also positioned at the outermost periphery of a pattern region on the replica mold. Therefore, even during the imprint process using this replica mold, wetting and spreading (flow) of the imprint resin are not inhibited. According to the imprint mold (master mold) 1 of the present embodiment, in the imprint process performed on the imprint mold (replica mold) with a reversed uneven structure that is produced through imprint lithography using the imprint mold, the concave portions of the dummy patterns can sufficiently be filled with the imprint resin, preventing the occurrence of the defects caused by non-filling of the imprint resin.

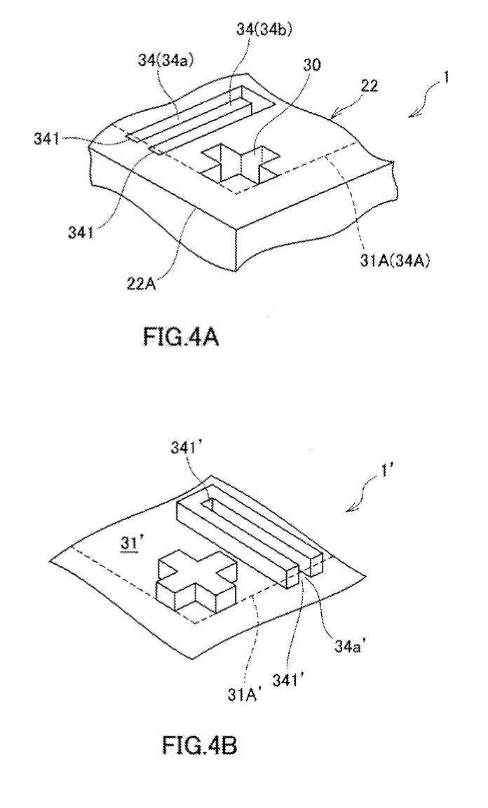

On the other hand, the aspect shown in FIG. 4(a) is considered in which the both end portions 341, 341 of the concave portion 34a of each dummy pattern 34 reach the same side out of the sides configuring the outermost periphery 31A of the pattern region 31 (e.g., the concave portion 34a of each dummy pattern 34 is in the shape of substantially an inverted “C”).

In this case, the imprint resin flows along the flow path constructed of the concave portion 34a of each dummy pattern 34 in the imprint process using the imprint mold 1. Therefore, the flow of the imprint resin is not blocked.

However, as to an imprint mold (replica mold) 1′ that is produced through imprint lithography by using the imprint mold 1 as a master mold, as shown in FIG. 4(b), one of end portions 341′ of each of concave portions 34a′ is positioned at an outermost periphery 31A′ of a pattern region 31′, while the other end portion 341′ is positioned inside the pattern region 31′, the concave portions 34a′ being formed to correspond to the convex portions 34b surrounded by the concave portions 34a. In the imprint process using this imprint mold 1′, the flow of the imprint resin is not blocked when the imprint resin flows toward the outermost periphery 31A′ of the pattern region 31′ along a flow path constructed of the concave portion 34a′, but is likely to be blocked by the other end portion 341′ when the imprint resin flows toward substantially the center of the pattern region 31′.

Therefore, in the imprint mold 1 according to the present embodiment, when the both end portions 341, 341 of the concave portion 34a of each dummy pattern 34 reach the outermost periphery 31A of the pattern region 31, it is particularly preferred that the end portions 341, 341 respectively reach two different sides of the four sides configuring the outermost periphery 31A of the pattern region 31 (see FIG. 3).

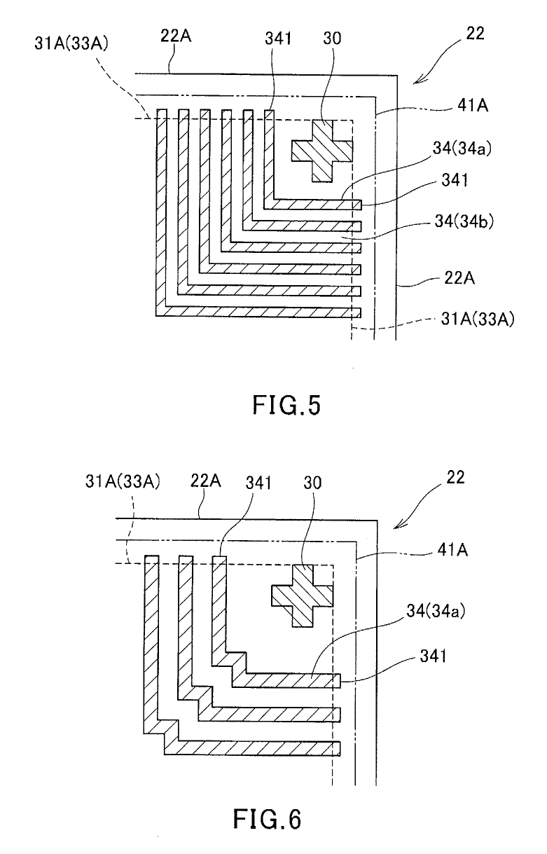

When the imprint mold 1 has the mesa structure 22 as in the present embodiment, it is preferred that at least one end portion 341 (preferably the both end portions 341, 341) of the concave portion 34a (or convex portion 34b) of each dummy pattern 34 is located between the outermost periphery 22A of the mesa structure 22 and the outermost periphery 31A of the pattern region 31 but on the pattern region 31 side of an intermediate position 41A between the outermost peripheries 22A, 31A, as shown in FIGS. 5 and 6. If one of the end portions 341 of the concave portion 34a (or convex portion 34b) of each dummy pattern 34 is located further toward the outermost periphery 22A side of the mesa structure 22 than the intermediate position 41A, there is a possibility that, during the imprint process using the imprint mold 1, the imprint resin might leak to the outside of the mesa structure 22 through the flow path constructed of the concave portion 34a of each dummy pattern 34. When the imprint resin leaks to the outside of the mesa structure 22, the leaked imprint resin becomes a foreign matter, causing defects.

Note that, when the imprint mold 1 according to the present embodiment is in the shape of a flat plate without the mesa structure 22, the imprint process using this flat imprint mold generally uses a base material with a mesa structure as the substrate to be processed. Therefore, when the imprint mold according to the present embodiment is a flat imprint mold, the location of one of the end portions (preferably the both end portions) of the concave portion (or convex portion) of each dummy pattern may be set properly in consideration of the positional relationship thereof with the outermost periphery of the mesa structure of the base material that is used as the substrate to be processed.

The size of each dummy pattern 34 is not particularly limited and can be set properly so that the original function of a dummy pattern (improving the detachability of the imprint mold, the fillability of the imprint resin, etc.) can be exerted effectively.

The imprint mold 1 according to the present embodiment that has the foregoing configuration can be used favorably in a pattern formation method described hereinafter.

First, the substrate to be processed that has the imprint resin as a material to be transferred, fed to one side thereof, and the imprint mold 1 according to the present embodiment, are placed face to face. The principal surface 2a of the imprint mold 1 and the imprint resin are brought into contact with each other, and then the imprint resin is expanded (wet and spread) between the principal surface 2a of the imprint mold 1 and one side of the substrate to be processed. In so doing, because the concave portion 34a of each dummy pattern 34 is not surrounded with the corresponding concave portion 34b in the pattern region 31 of the imprint mold 1 according to the present embodiment, the imprint resin that flows through the flow path constructed of the concave portion 34a of each dummy pattern 34 cannot be blocked. As a result, the concave portion 34a of each dummy pattern 34 can sufficiently be filled with the imprint resin.

Thereafter, the imprint resin is hardened, and then the hardened imprint resin and the imprint mold 1 are separated from each other. As a result, the main pattern and dummy patterns 34 of the imprint mold 1 are transferred, successfully forming, on the substrate to be processed, the fine uneven patterns that have no defects caused by non-filling of the imprint resin.

By etching the substrate to be processed using the resultant fine uneven patterns as masks, an imprint mold (replica mold) or the like can be formed in which its main pattern and dummy patterns are obtained by reversing the uneven structure of the main pattern and dummy patterns 34 of the imprint mold 1. The replica mold produced as such can also be used in the foregoing pattern formation method, as with the imprint mold 1 according to the present embodiment.

In the imprint mold 1 of the present embodiment with the foregoing configuration where the imprint resin flows through the flow path constructed of the concave portion 34a of each dummy pattern 34 and is wet and spread within the pattern region 31 in the imprint process using the imprint mold 1, the flow of the imprint resin is not blocked because the concave portion 34a of each dummy pattern 34 is not surrounded with the corresponding convex portion 34b in the pattern region 31 of the imprint mold 1.

With the imprint mold (replica mold), too, which is produced through imprint lithography by using the imprint mold 1 of the present embodiment as a master mold, the imprint resin flows through the flow path constructed of the concave portion of each dummy pattern and is wet and spread in the pattern region in the imprint process using the replica mold, in the manner described above. In this case as well, the flow of the imprint resin is not blocked because the concave portion of each dummy pattern on the replica mold is not surrounded with the corresponding convex portion in the pattern region.

For this reason, either in the imprint process using this imprint mold 1 or in the imprint process using the imprint mold (replica mold) that is produced from the imprint mold 1 and thus has a dummy pattern obtained by reversing the uneven structure of the dummy patterns 34 of the imprint mold 1, the imprint mold 1 of the present embodiment can realize the effect of sufficiently filling the concave portion of each dummy pattern with the imprint resin and thereby preventing the occurrence of the defects caused by non-filing of the imprint resin.

[Dummy Pattern Designing Method]

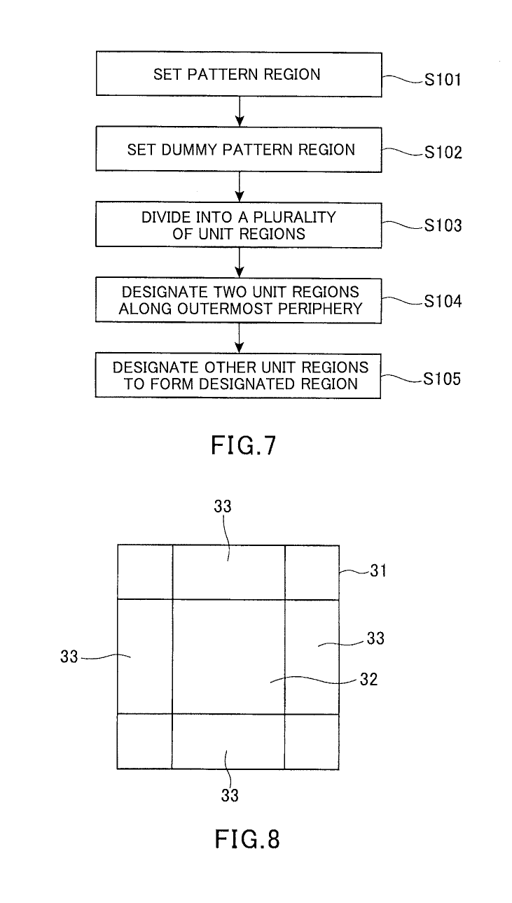

A method for designing the dummy patterns of the imprint mold is described next. FIG. 7 is a flowchart showing a dummy pattern designing method according to the present embodiment.

As shown in FIG. 7, in the dummy pattern designing method according to the present embodiment, first, a pattern region is set in order to form the fine uneven patterns, such as the main pattern and dummy patterns, in the imprint mold (S101).

When the imprint mold according to the present embodiment has a base portion and a projected structure (mesa structure) projecting from one surface of the base portion (see FIG. 1), a region that is smaller than the outer periphery of the mesa structure in a plan view is set as the pattern region.

Also, when the imprint mold according to the present embodiment is in the shape of a flat plate, a substrate (mesa substrate) that has a base portion and a projected structure (mesa structure) projecting from one surface of the base portion is usually used as the substrate to be processed in the imprint process using this flat imprint mold, and then the main pattern and dummy patterns of the imprint mold are transferred onto the mesa structure of this mesa substrate. Therefore, a region that is planarly smaller than the mesa structure of the mesa substrate used as the substrate to be processed can be set as the pattern region of the flat imprint mold.

Regions for forming the alignment marks can be set at least in the vicinity of the four corners of the pattern region in order to align the imprint mold with the substrate to be processed in the imprint process using the imprint mold.

Next, the dummy pattern region for forming the dummy patterns is set within the pattern region (S102).

For instance, when the imprint mold according to the present embodiment has one main pattern region located in substantially the center of the pattern region, a region other than the main pattern region inside the pattern region is set as the dummy pattern region (see FIG. 2).

There may be a single dummy pattern region in the pattern region or a plurality of dummy pattern regions sectioned in the pattern region. For example, as shown in FIG. 8, a plurality of the dummy pattern regions 33 may be set along each side of the substantially square main pattern region 32 that is located substantially at the center of the pattern region 31.

Subsequently, the dummy pattern region set in step S102 described above is sectioned into a plurality of unit regions (S103). When forming a resist pattern using, for example, an electron beam lithography apparatus in the course of producing the imprint mold, the size of each unit region can be set to be equal to or greater than the minimum drawing size set in the electron beam lithography apparatus.

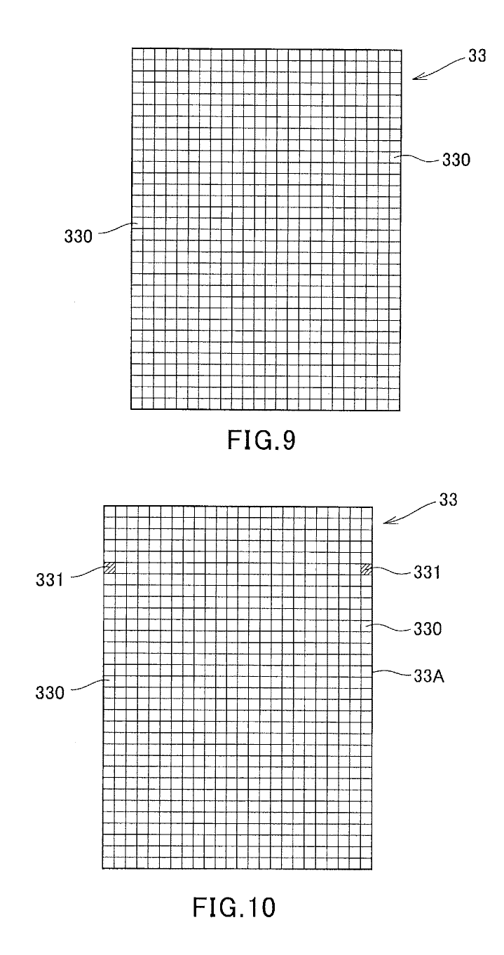

The shape of each unit region is not particularly limited, and examples thereof include a substantially square shape and a substantially circular shape. It is preferred in the present embodiment that the dummy pattern region be entirely packed with the plurality of unit regions. Therefore, when the dummy pattern region 33 is in a substantially square shape, it is preferred that each of these unit regions 330 be in a substantially square shape as well (see FIG. 9).

Then, of the unit regions located at the outermost periphery of the dummy pattern, two unit regions are designated (S104). It is preferred that these two unit regions be randomly selected and designated from among the unit regions that are located on two different sides out of the four sides configuring the outermost periphery of the dummy pattern region. Each of the unit regions designated in this manner is an electron beam drawing region (or an electron beam non-drawing region) obtained in the course of producing the imprint mold and is also a region configuring each end portion of the concave portion (or convex portion) of each of the dummy patterns of the imprint mold to be produced. Therefore, the both end portions of the concave portion (or convex portion) of each of the dummy patterns of the imprint mold to be designed and produced in the present embodiment reach the outermost periphery of the dummy pattern region.

For instance, as shown in FIG. 10, of the unit regions 330 located along the outermost periphery 33A of the dummy pattern region 33, unit regions 331, 331 that are located along two different sides configuring the dummy pattern region (two sides facing each other in the example shown in FIG. 10) are designated.

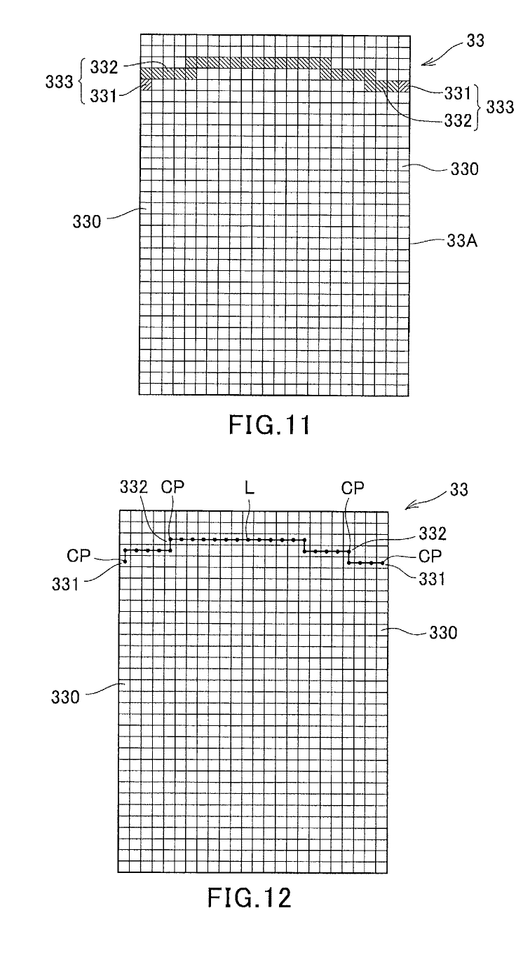

Next, unit regions other than the two unit regions designated in S104 described above (the designated unit regions) are designated, to construct a designated region by connecting the two designated unit regions with these other unit regions therebetween (S105). In so doing, the designated region is formed in such a manner that all of the unit regions configuring the designated region each share one side of the designated region with the adjacent unit regions. For example, as shown in FIG. 11, other unit regions 332 are designated in such a manner as to connect the two designated unit regions 331, 331 located along the outermost periphery 33A of the dummy pattern region 33, to form a single designated region 333. The other unit regions 332 designated in S105 may be the unit regions 330 located along the outermost periphery 33A of the dummy pattern region 33 (except for the two designated unit regions 331 designated in S104), or may be the unit regions 330 that are not located along the outermost periphery 33A of the dummy pattern region 33.

The designated region 333 that is formed by the unit regions 331, 332 designated in the foregoing steps S104 and S105 configures the electron beam drawing region or electron beam non-drawing region in the course of producing the imprint mold, the electron beam drawing region or electron beam non-drawing region being a concave portion or convex portion of each of the dummy patterns on the imprint mold. Therefore, as a result of connecting the two designated unit regions 331, 331 with the adjacent unit regions 332 sharing one side of the designated region therewith, the both end portions of the concave portion (or convex portion) of each dummy pattern of the imprint mold reaches the outermost periphery of the dummy pattern region. For this reason, the concave portion of each dummy pattern does not exist independently in the pattern region (dummy pattern region) of the imprint mold. Consequently, a dummy pattern that does not block the flow of the imprint resin in the imprint process using the imprint mold can be designed.

A method for designating the other unit regions 332 is not particularly limited and links any points (e.g., center points CP) between the two designated unit regions 331, 331 with a line (a straight line or a polygonal line) L, as shown in FIG. 12. In so doing, the line L is drawn to link the points (e.g., center points CP) of all the other unit regions 332 that connect the two designated unit regions 331, 331 and to intersect with two sides (opposing two sides or adjacent two sides) of each of other unit regions 332. In other words, in each of the other unit regions 332 connecting the two designated unit regions 331, 331, the line L is drawn to connect the sides that are shared by two other unit regions 332, 332 adjacent to the other unit regions 332. Then, all the other unit regions 332 through which the line L passes are designated. As a result, the other unit regions 332 connecting the two designated unit regions 331, 331 can be designated.

The other unit regions 332 are designated in S105 in such a manner that the unit regions (undesignated unit regions) 330 that are not designated in S104 and S105 are not surrounded by the single designated region 333 that is formed by the two designated unit regions 331, 331 and the other unit regions 332 connecting therebetween. In other words, the other unit regions 332 are designated so as not to form a loop within the dummy pattern region 33 by the single designated region 333. If the undesignated unit regions 330 are surrounded with the designated region 333, the concave portions of the dummy patterns on the imprint mold, which are formed to correspond to the respective undesignated unit regions 330 surrounded with the designated region 333, are isolated in the pattern region (dummy pattern region), blocking the flow of the imprint resin during the imprint process using the imprint mold.

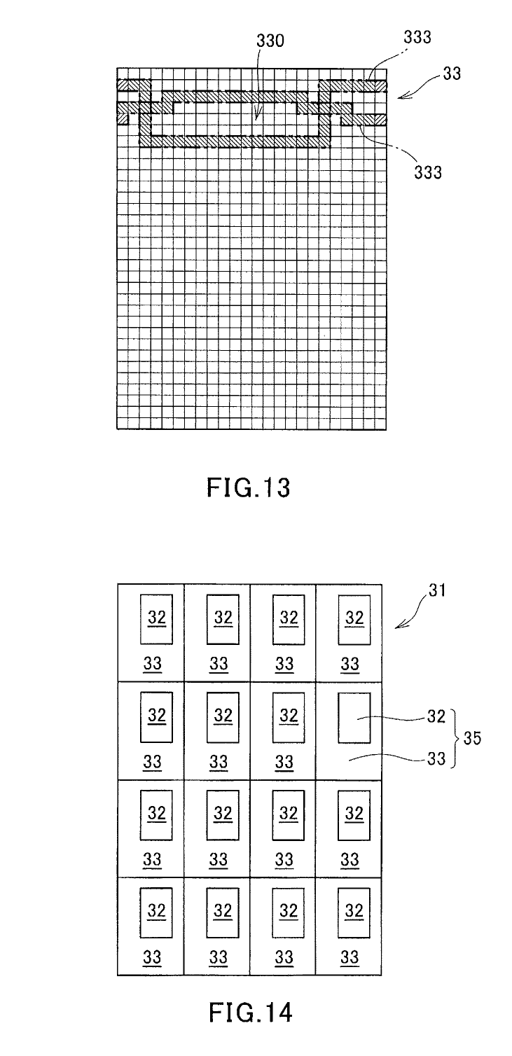

The steps S104 and S105 are repeated to form the designated regions to correspond to all of the dummy patterns (concave portions or convex portions) in the dummy pattern region. In so doing, it is not a problem that one of the designated regions intersects with or is connected to another designated region, but two or more designated regions are crossed with or connected to each other so that the undesignated unit regions do not exist independently in the dummy pattern region. For example, in a case where the undesignated unit regions 330 are surrounded by two designated regions 333 within the dummy pattern region 33 as a result of crossing or connecting the designated regions 333, 333, as shown in FIG. 13, the steps S104 and S105 need to be executed again.

According to the dummy pattern designing method of the present embodiment described above, the dummy pattern can be designed in such a manner that the concave portion of the dummy pattern of the imprint mold is not surrounded with the convex portion of the dummy pattern in the pattern region (dummy pattern region). Therefore, producing an imprint mold based on the design obtained by the dummy pattern designing method of the present embodiment can prevent the occurrence of the defects caused by not filling the concave portion of the dummy pattern with the imprint resin, because the concave portion of each dummy pattern does not exist in the form of the regions closed in the pattern region (dummy pattern region) (closed region) in the imprint process using the imprint mold.

Particularly, according to such an imprint mold that is produced based on the dummy pattern design obtained by the dummy pattern designing method of the present embodiment, in the replica mold with a reversed uneven structure that is obtained through imprint lithography using the imprint mold, the concave portion of each dummy pattern does not exist in the form of the closed region in the pattern region (dummy pattern region) during the imprint process.

Thus, in the imprint mold that is produced based on the dummy pattern design obtained by the dummy pattern designing method of the present embodiment and in the replica mold with a reversed uneven structure that is obtained through imprint lithography using this imprint mold, the dummy pattern designing method according to the present embodiment can easily design a dummy pattern that accomplishes prevention of the defects that are caused by not filling the concave portions of the dummy patterns with the imprint resin in the imprint process.

The foregoing embodiment is to facilitate understanding of the present invention and is not to limit the present invention. Each of the elements disclosed in the foregoing embodiment, therefore, is intended to include all design changes and equivalents thereof falling within the technical scope of the present invention.

The foregoing embodiment has described an example of the imprint mold 1 in which the main pattern region 32 is located substantially at the center of the pattern region 31 and the dummy pattern region 33 is arranged to surround the main pattern region 32, and an example of the dummy pattern designing method for the imprint mold 1 having such configuration. However, the imprint mold and the dummy pattern designing method according to the present invention are not limited to these aspects.

For example, another embodiment of the present invention takes an example of an imprint mold in which the main pattern (main pattern region 32) is arranged in a plurality of arrays in the pattern region 31 and the dummy pattern region 33 is arranged between the main pattern regions 32, as shown in FIG. 14, and an example of the dummy pattern designing method for this imprint mold.

In the imprint mold shown in FIG. 14, one end portion, or preferably both end portions, of a concave portion (or convex portion) of a dummy pattern formed in each dummy pattern region 33 reaches the outermost periphery of the pattern region 31, when the entire pattern region 31 is viewed. The imprint mold with this aspect can bring about the effect of sufficiently filling the concave portions of the dummy patterns of all of the dummy pattern regions 33 of the pattern region 31 with the imprint resin.

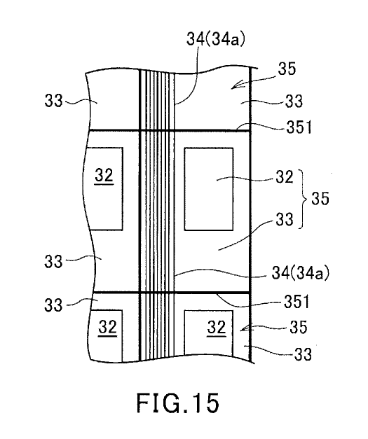

The method for designing a dummy pattern for this imprint mold designs a dummy pattern such that one end portion 341, or preferably the both end portions 341, 341, of the concave portion 34a (or convex portion 34b) of each dummy pattern 34 formed in the dummy pattern region 33 reaches the outermost periphery of a pattern small region 35 configured by one main pattern region 32 and the dummy pattern region 33 located around the main pattern region 32 as shown in FIG. 15, and such that, when one end portion 341 of the concave portion 34a (or convex portion 34b) of each dummy pattern 34 formed in the dummy pattern region 33 of one pattern small region 35 reaches a boundary 351 between this pattern small region 35 and the adjacent pattern small region 35, one end portion 341 of the concave portion 34a (or convex portion 34b) of this dummy pattern 34 is connected to one end portion 341 of the concave portion 34a (or convex portion 34b) of the dummy pattern 34 formed in the dummy pattern region 33 of this adjacent pattern small region 35.

In this case, when arranging a plurality of pattern small regions 35 in array, the dummy pattern region 33 may be designed for each pattern small region 35 in such a manner that the end portions 341 of the concave portions 34a (or convex portions 34b) of the dummy patterns 34 of the pattern small regions 35 adjacent to each other are connected to each other by the boundary 351.

In the foregoing embodiment, the dummy pattern region is divided into a plurality of unit regions, and unit regions are designated in such a manner as to connect the two unit regions located at the outermost periphery of the dummy pattern region, to construct a designated region. The designated region is disposed as a dummy pattern. However, the method for disposing the dummy pattern in the dummy pattern region is not limited to this method. For example, a plurality of lines (straight lines or polygonal lines) may be drawn to connect two random points located at the outermost periphery of the dummy pattern region, and the regions between two adjacent lines may be disposed as the concave portions or convex portions of the dummy pattern. This may be done so as not to form a region that is surrounded with a plurality of lines drawn within the dummy pattern region.

### INDUSTRIAL APPLICABILITY

The present invention is helpful in producing and designing an imprint mold that is used in a nanoimprint process for forming a fine uneven pattern in a semiconductor device producing process and the like.

### REFERENCE SIGNS LIST

1, 1′ Imprint mold
2 Base material

21 Base portion

22 Projected structure (mesa structure) Pattern region
31 Main pattern region
32 Dummy pattern region
33 Dummy pattern

34a Concave portion (concave structure)

34b Convex portion (convex structure)

1. An imprint mold, comprising, in a pattern region on a principal surface of a base material, a main pattern with an uneven structure and a dummy pattern with an uneven structure for assisting transfer of the main pattern,
wherein at least one end portion of a concave structure or a convex structure of the dummy pattern reaches an outermost periphery of the pattern region, and
a closed region that is surrounded with one or more concave structures or convex structures of the dummy pattern does not exist in the pattern region when the imprint mold is planarly viewed.

2. The imprint mold according to claim 1, wherein both end portions of the concave structure or the convex structure of the dummy pattern reach the outermost periphery of the pattern region.

3. The imprint mold according to claim 2, wherein
the pattern region is a substantially square region, and
the both end portions of the concave structure or the convex structure of the dummy pattern respectively reach two different sides out of four sides configuring the substantially square pattern region.

4. The imprint mold according to claim 1, wherein
the imprint mold comprises a base portion and a projected structure portion protruding from a surface of the base portion, and the outermost periphery of the pattern region is located on the inside of an outermost periphery of the projected structure portion.

5. The imprint mold according to claim 4, wherein at least one end portion of the concave structure or the convex structure of the dummy pattern is located on a side of the outermost periphery of the pattern region between the outermost periphery of the projected structure portion and the outermost periphery of the pattern region.

6. The imprint mold according to claim 1, wherein
the pattern region is a region in which a plurality of pattern small regions are arranged in array,
the main pattern and the dummy pattern are formed in each of the plurality of pattern small regions,
from among the plurality of pattern small regions, at least one end portion of a concave structure or a convex structure of a dummy pattern of the pattern small region that is located at the outermost periphery formed in the pattern region reaches the outermost periphery of the pattern region, and
a concave structure or a convex structure of the dummy pattern formed in one of the pattern small regions is connected to a concave structure or a convex structure of the dummy pattern formed in another pattern small region adjacent to the pattern small region.

7. A method for designing a dummy pattern for an imprint mold that is formed with, in a pattern region on a principal surface of a base material, a main pattern with an uneven structure and the dummy pattern with an uneven structure for assisting transfer of the main pattern, the method comprising:
a dummy pattern region setting step of setting a dummy pattern region for forming the dummy pattern in the pattern region of the imprint mold; and
a dummy pattern arrangement step of arranging the dummy pattern in the dummy pattern region,
wherein, in the dummy pattern arrangement step, the dummy pattern is arranged in the dummy pattern region in such a manner that at least one end portion of a concave structure or a convex structure of the dummy pattern reaches an outermost periphery of the pattern region and that a region surrounded with one or more concave structures or convex structures of the dummy pattern is not formed within the dummy pattern region.

8. The dummy pattern designing method according to claim 7, wherein, in the dummy pattern arrangement step, the dummy pattern is arranged in the dummy pattern region in such a manner that both end portions of the concave structure or a convex structure of the dummy pattern reach the outermost periphery of the pattern region.

9. The dummy pattern designing method according to claim 8, wherein
the dummy pattern region is divided into a plurality of unit regions, and
the dummy pattern arrangement step arranges, in the dummy pattern region, a region configured by connecting any two unit regions to each other with other unit regions therebetween, as the concave structure or a convex structure of the dummy pattern, these two unit regions being located respectively at the outermost periphery of the pattern region and an outermost periphery of the dummy pattern region.

10. The dummy pattern designing method according to claim 8, wherein the dummy pattern arrangement step draws a plurality of lines to connect any two points located respectively at the outermost periphery of the pattern region and the outermost periphery of the dummy pattern region, and arranges two adjacent lines out of the plurality of lines in the dummy pattern region as the concave structure or the convex structure of the dummy pattern.

11. The dummy pattern designing method according to claim 7, wherein
the imprint mold comprises a base portion and a projected structure portion protruding from a surface of the base portion, and
the outermost periphery of the pattern region is located on the inside of an outermost periphery of the projected structure portion.

12. The dummy pattern designing method according to claim 11, wherein, in the dummy pattern arrangement step, the dummy pattern is arranged in the dummy pattern region in such a manner that at least one end portion of the concave structure or the convex structure of the dummy pattern is located on a side of the outermost periphery of the pattern region between the outermost periphery of the projected structure portion and the outermost periphery of the pattern region.

13. The dummy pattern designing method according claim 7, wherein
the pattern region is a region in which a plurality of pattern small regions are arranged in array,
the dummy pattern region setting step sets a dummy pattern region for forming the dummy pattern, in each of the pattern small regions, and
the dummy pattern arrangement step arranges the dummy pattern in such a manner that, from among the plurality of pattern small regions, at least one end portion of the concave structure or the convex structure of the dummy pattern within the dummy pattern region of a pattern small region located at the outermost periphery of the pattern region reaches the outermost periphery of the pattern region and that the concave structure or the convex structure of the dummy pattern within the dummy pattern region of one of the pattern small regions is connected to the concave structure or the convex structure of the dummy pattern within the dummy pattern region of another pattern small region adjacent to the pattern small region.

14. A pattern formation method, comprising:
placing, face to face, a substrate to be processed, one surface of which is fed with a material to be transferred and the imprint mold of claim 1;
bringing a principal surface of the imprint mold into contact with the material to be transferred;
expanding the material to be transferred between the principal surface of the imprint mold and the one surface of the substrate to be processed;
hardening the material to be transferred; and
separating the hardened material to be transferred from the imprint mold.
